(19) United States
(12) Patent Application Publication
(10) Pub. No.: US 2026/0179892 A1
(43) Pub. Date: Jun. 25, 2026

(54) GAS ANALYSIS DEVICE AND CONTROL METHOD

(71) Applicant: ATONARP INC., Tokyo (JP)

(72) Inventors: Hirofumi NAGAO, Tokyo (JP); Shinichi MIKI, Tokyo (JP); Naoki TAKAHASHI, Tokyo (JP); Prakash Sreedhar MURTHY, Tokyo (JP)

(73) Assignee: ATONARP INC., Tokyo (JP)

(21) Appl. No.: 19/532,462

(22) Filed: Feb. 6, 2026

Related U.S. Application Data
(63) Continuation of application No. 18/704,959.

(30) Foreign Application Priority Data
Oct. 29, 2021 (JP) 2021-178175

(51) Int. Cl. H01J 37/32

(52) U.S. Cl. CPC H01J 37/32981; H01J 37/32348; H01J 37/32449; H01J 37/32834; H01J 37/32963; H01J 37/32972; H01J 2237/332; H01J 2237/334; H01J 2237/335

(57) ABSTRACT

A gas analyzer apparatus includes: a sample chamber that is provided with a dielectric wall structure and into which a sample gas to be measured flows; a plasma generation mechanism for generating plasma inside the sample chamber, which has been depressurized, using an electric field and/or a magnetic field through the dielectric wall structure; a gas input apparatus configured to cause only the sample gas to flow from a process into the sample chamber; a first detector configured to detect components in the plasma by filtered ionized gas from the generated plasma; and a second detector configured to analyze light emission of ions in the plasma inside the sample chamber and output a second detection result that is to be synchronized with the first detection result of the first detector.

### CROSS REFERENCE TO RELATED APPLICATIONS

The present application is a continuation of U.S. patent application Ser. No. 18/704,959, which was filed on Apr. 26, 2024, which is a national stage application of PCT/JP2022/038848, which was filed on Oct. 19, 2022, which claims priority to Japanese Patent Application No. 2021-178175, which was filed on Oct. 29, 2021. The contents of U.S. patent application Ser. No. 18/704,959, PCT/JP2022/038848 and Japanese Patent Application No. 2021-178175 are incorporated herein by reference in their entirety.

### TECHNICAL FIELD

The present invention relates to a gas analyzer apparatus and a control method for the same.

### BACKGROUND ART

Japanese Laid-open Patent Publication No. 2016-27327 discloses a glow discharge optical emission spectrometry (GD-OES) apparatus in which the sample holder includes an electrode (second electrode), which has a sample fixing surface, and an outer cylinder portion and an inner cylinder portion (contacting portion) inside which the sample fixing surface is disposed. In a state where the sample is located away from the opening of a glow discharge tube, the open end of the inner cylindrical portion is brought into contact with the peripheral edge of the opening. The inside of the glow discharge tube, the outer cylindrical portion, and the inner cylindrical portion that have been connected is depressurized and argon gas is supplied. The inner cylindrical portion is then moved relative to the outer cylindrical portion to place the sample closer to the tip of a cylindrical part (end portion) of the anode (first electrode) of the glow discharge tube, coolant is supplied on a flow path (cooling portion) to cool the sample, and a voltage is applied to the electrodes to perform glow discharge optical emission spectrometry.

### SUMMARY OF INVENTION

In the field of gas analyzer apparatuses that detect components contained in a sample gas by ionizing the sample gas, there is demand for a gas analyzer apparatus capable of performing detection more stably or with even higher accuracy.

One aspect of the present invention is a gas analyzer apparatus including: a sample chamber that is provided with a dielectric wall structure and into which a sample gas to be measured flows; a plasma generation mechanism that is configured to generate a plasma in the sample chamber, which has been depressurized, using an electric field and/or a magnetic field through the dielectric wall structure; a gas input apparatus that is configured to cause only the sample gas to flow from a process into the sample chamber; a first detector that is configured to detects components in the plasma by filtered ionized gas from the generated plasma; and a second detector that is configured to analyze emission (light emission) of ions in the plasma inside the sample chamber and output a second detection result that is to be synchronized with a first detection result of the first detector. In this gas analyzer apparatus, the second detector is capable of optical emission analysis of the plasma that is the ion source of the first detector. This means that a common (identical) ionized sample can be analyzed using different methods synchronously, that is, simultaneously in parallel, or with a limited time interval (or latency) or time lag that is unique to this gas analyzer apparatus and can be set in advance, and analysis data can be generated by associating the different detection results obtained by these different methods.

Typically, due to the need to change the detection conditions at the filter, the first detection result includes a mass spectrum acquired by time division (that is, over time), which is to say serially (sequentially). On the other hand, the second detection result includes an emission spectrum (optical emission spectrum) that can be obtained in parallel by spectrometry. This gas analyzer apparatus includes the sample chamber that generates the plasma, which serves as both the ion source and light emission source, separately from the process, and includes the first detector and the second detector on a fixed route with respect to the sample chamber. Accordingly, serial first detection results and parallel second detection results for the same plasma that is generated inside the sample chamber can be synchronously acquired, and such sets of data can be associated to generate and output as data for analysis (analysis data). This means that, for example, by checking for fluctuations in the second detection results that are acquired in parallel during the time period in which the first detection results are being acquired serially, it is possible to verify that the first detection results are information from plasma under the same conditions (as examples, plasma from a process under the same conditions or plasma being maintained at the same conditions), which means that even more reliable analysis results can be obtained.

By generating microplasma in the sample chamber of the gas analyzer apparatus, it is possible to reduce the volume of the common ion source and emission source subjected to detection, which makes it possible for the first detection results and the second detection results to be obtained for the same (identical) target (plasma) in volume and/or condition. In addition, it is also possible to limit the mass spectrum that is serially obtained to a region of interest (ROI), to check information for a wide range using the second detection results that are obtained in parallel, and to acquire information on the ROI using the first detection result acquired serially. This means that it is possible, while still confirming information for a wide range by the second detection results, to obtain an even more accurate analysis result for the ROI by the first detection results, even at short time intervals and including variations over time.

The gas analyzer apparatus may include a first analyzer that analyzes the sample gas based on the first detection result and a second detection result that has been synchronized with the first detection result with a time lag (a delay, a time interval) defined by the gas analyzer apparatus. Due to the difference in spectral interference between the first detection result and the second detection result, more accurate analysis can be performed through collaborative use of these detection results.

Another aspect of the present invention is a method of controlling a system including a gas analyzer apparatus. The method includes outputting in synchronization a first detection result of a first detector and a second detection result of a second detector. This outputting in synchronization may include associating and outputting the first detection result, which includes a mass spectrum acquired according to time division, that is, serially, and the second detection result, which includes a parallel emission spectrum that can be synchronized and compared with the first detection result. The mass spectrum may include a mass spectrum limited to a range of interest (ROI).

Yet another aspect of the present invention is a program (program product) that enables a computer to control a system including the gas analyzer apparatus described above according to the method described above. The program includes instructions for executing control of the system. The program may be provided having been recorded on a computer-readable recording medium.

### BRIEF DESCRIPTION OF DRAWINGS

FIG. 1 is a block diagram depicting the schematic configuration of a process monitoring system including a gas analyzer apparatus.

FIG. 2 depicts one example of analysis data.

FIG. 3 is a flowchart depicting an overview of the operation of a process monitor.

FIG. 4 depicts another example of a process monitoring system including a gas analyzer apparatus.

FIG. 5 depicts yet another example of a process monitoring system including a gas analyzer apparatus.

### DESCRIPTION OF EMBODIMENTS

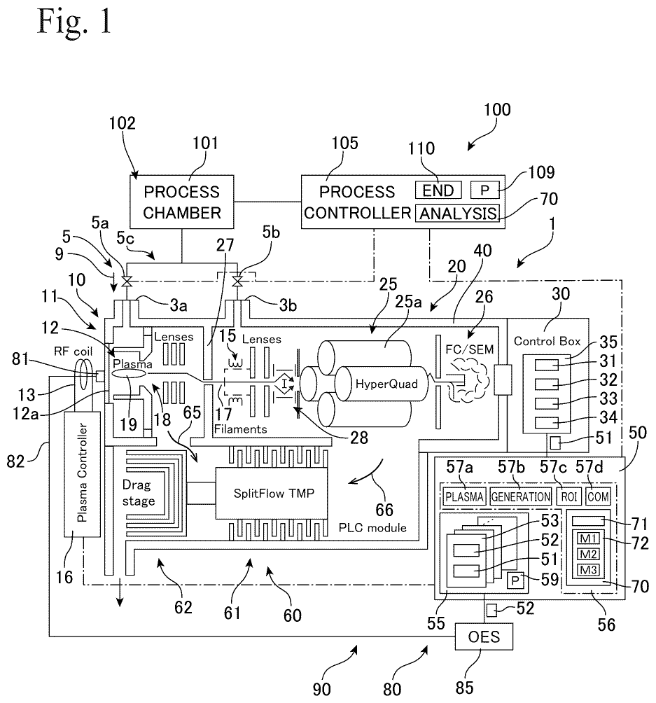

FIG. 1 depicts the schematic configuration of a process monitoring system 100 as one example of a system including a gas analyzer apparatus 1. The gas analyzer apparatus 1 analyzes a sample gas 9 supplied from a process chamber 101 in which one or more plasma processes 102 is performed. The plasma processes 102 performed in the process chamber 101 are typically processes for forming various types of films or layers on substrates or processes for etching substrates and may include CVD (Chemical Vapor Deposition) or PVD (Physical Vapor Deposition). The plasma processes 102 are not limited to processes related to semiconductor manufacturing, and may be processes of laminating various types of thin film on optical components, such as lenses, filters, or the like, as substrates.

As one example, in the field of semiconductors, semiconductor chip structures have become increasingly three-dimensional in recent years due to demands for increased memory capacity, improvements in logic speed, and reduced power consumption. This means that for semiconductor process control, there have been the problems of processes becoming more complex, an increased demand for atom-level quality, and an increase in the cost of measurement and monitoring. Monitoring of gas including reactants and by-products is important for process matching, for measurement of transition points during deposition, and for detection of endpoints during etching. With optical emission spectrometry (Optical Emission Spectroscopy, OES) which is presently in standard use, it is difficult to comprehensively monitor processes. On the other hand, residual gas analyzers and mass spectrometers with ion sources that use a regular hot filament may face a problem of reduced lifespan due to damage caused by semiconductor gases.

In the process monitoring system 100 that uses the gas analyzer apparatus 1 according to the present embodiment, it is possible to provide innovative process control by performing real-time monitoring, even in a harsh environment and providing highly reliable measurement results. The gas analyzer apparatus 1 functions as a total solution platform developed for the purpose of dramatically improving the throughput in semiconductor chip manufacturing and maximizing the yield rate. As described above, the gas analyzer apparatus 1 according to the present embodiment has an extremely small installation footprint, and can therefore be directly connected to the chamber 101 and used on site. In addition, a standard protocol that is currently implemented in lots of semiconductor manufacturing process equipment, such as the EtherCAT protocol, can be installed in the PLC 50 and integrated into the process equipment control system 100.

The gas analyzer apparatus 1 includes an ionization apparatus 10 that generates ions (ion flow) 17 of the sample gas 9 and a sensor group (sensor suite or analyzer group) 90 that detects ions supplied from the ionization apparatus 10 or generated at the ionization apparatus 10. The ionization apparatus 10 includes a plasma generation unit (plasma generation apparatus) 11 for generating plasma 19 of the sample gas 9 to be measured that is supplied from the process 102 via a sample input 3a. The plasma generation unit 11 includes a chamber (sample chamber) 12 that is equipped with a dielectric wall structure 12a and into which the sample gas 9 to be measured flows, a high-frequency wave supplying mechanism (RF supplying mechanism or plasma generating mechanism) 13 that uses a high-frequency electric and/or magnetic field applied via the dielectric wall structure 12a to generate the plasma 19 inside the sample chamber 12 that has been depressurized, and a plasma controller 16 that controls the frequency and power of the high-frequency waves. The plasma 19 is supplied as an ion flow 17 from an opening 18 provided at one end of the sample chamber 12 to a first detector 20, described later. The gas analyzer apparatus 1 includes a gas input apparatus 5 configured to allow only the sample gas 9 from the process chamber 101 in which the plasma process 102 is performed to flow into the sample chamber 12.

The gas analyzer sensor group 90 includes a first detector 20 that detects components in the plasma by filtered ionized gas of the plasma 19 that is supplied as ions (the ion flow) 17, and a second detector 80 for analyzing (through spectroscopic analysis) the emission (light emission) of ions in the plasma 19 inside the sample chamber 12. One example of the first detector (first sensor, first detector, or first measuring apparatus) 20 is a mass spectrometry-type detector (mass spectrometer (MS)). The first detector 20 includes a filter unit (mass filter, in the present embodiment, a quadrupole filter) 25 for filtering the ionized sample gas (sample gas ions) 17 according to mass-to-charge ratio and a detector 26 that detects the filtered ions. The gas analyzer apparatus 1 further includes a vacuum chamber (housing) 40 that houses the filter unit 25 and the detector 26, and an exhaust system 60 that keeps the inside of the housing 40 under appropriate negative pressure conditions (that is, vacuum conditions).

The exhaust system 60 in the present embodiment includes a turbomolecular pump (TMP) 61 and a roots pump 62. The exhaust system 60 is a split-flow type that also controls the internal pressure of the sample chamber 12 of the plasma generation apparatus 11. The internal pressure of the chamber 12 is controlled by connecting a stage, out of the multistage TMP 61 of the exhaust system 60, that has a negative pressure suited to the internal pressure of the chamber 12, or by connecting the input of the roots pump 62 to the chamber 12.

Accordingly, the gas analyzer apparatus 1 according to the present embodiment includes an exhaust apparatus 60 for exhausting gas from the sample chamber 12, with the exhaust apparatus 60 including a first exhaust path 65 that exhausts gas from the sample chamber 12 while bypassing the first detector 20, and a second exhaust path 66 that exhausts via the first detector 20. By providing the first exhaust path 65 that exhausts from the sample chamber 12 directly while bypassing the first detector 20, it is possible to guide the sample gas 9 to the sample chamber 12 and control the internal pressure of the sample chamber 12 separately to control over the amount of gas that flows to the first detector 20 for filtering. This means that the amount of gas flowing through the first detector 20 can be stabilized, which means that the detection accuracy of the first detector 20 can be stabilized. On the other hand, since sufficient sample gas 9 can be drawn into the sample chamber 12 from the process via the gas input apparatus 5, it is possible to provide a gas analyzer apparatus 1 that is capable of monitoring the state (that is, variations) in the process chamber 101 in real time.

The mass filter 25 according to the present embodiment includes four tubular or cylindrical electrodes 25a whose inner surfaces are hyperbolic to form a hyperbolic electric field for filtering according to mass-to-charge ratio. The quadrupole-type mass filter 25 may have a large number, such as nine, of cylindrical electrodes arranged to form a matrix (array) so as to form a plurality of pseudo-hyperbolic electric fields. The detector 26 may include a Faraday Cap and a secondary electron multiplier, which may be used in combination or may be used interchangeably. The detector 26 may also be a different type, such as a channel electron multiplier or a microchannel plate.

The plasma generation apparatus 11 according to the present embodiment includes a sample chamber 12 for generating plasma that is integrally incorporated inside the housing 40. An outer shell of the chamber 12 is made of Hastelloy, has an insulated tubular electrode inserted therein, and internally generates the plasma 19. Only the sample gas 9 flows from the process chamber 101, in which the one or more processes 102 to be monitored are performed (carried out), via the gas input apparatus 5 from the sample input 3a into the depressurized sample chamber 12, so that the plasma 19 is formed in the sample chamber 12. That is, in the plasma generation apparatus 11, the plasma 19 to be analyzed is generated from only the sample gas 9 without using an assist gas (support gas) such as argon gas. The wall 12a of the sample chamber 12 is made of a dielectric member (dielectric body), examples of which include translucent dielectrics that are highly resistant to plasma, such as quartz, aluminum oxide (Al₂O₃) and silicon nitride (SiN₃).

In the plasma generation apparatus 11, a mechanism (RF supplying mechanism) 13 generates the plasma 19 inside the sample chamber 12 using an electric and/or magnetic field applied through the dielectric wall structure 12a without using a plasma torch. One example of the RF supplying mechanism 13 is a mechanism that excites the plasma 19 with high frequency (radio frequency, RF) power. Example methods for the RF supplying mechanism 13 include inductively coupled plasma (ICP), dielectric barrier discharge (DBD), and electron cyclotron resonance (ECR). A plasma generating mechanism 13 for generating plasma using these methods may include a high-frequency power source and an RF field forming unit. A typical RF field forming or inducing unit includes coils disposed along the sample chamber 12. The plasma generation apparatus 11 according to the present embodiment includes a function that causes ignition by changing the matching state by varying the frequency of the RF field. As one example, plasma can be generated and maintained by applying pulsed high-frequency power to ignite the plasma and then transitioning to a steady operating state. Note that although the plasma generation apparatus 11 may be a generator that forms inductively coupled plasma (ICP) using an assist gas, such as argon gas, and introduces the ICP into the sample gas to cause ionization, it is desirable to form the plasma 19 using only the sample gas, so that by generating microplasma, it is possible to make an assist gas unnecessary.

The internal pressure of the sample chamber 12 in the present embodiment is a pressure that facilitates the generation of plasma, and may be in a range of 0.01 to 1 kPa for example. When the internal pressure of the process chamber 101 is controlled to around 1 to several hundred Pa, the internal pressure of the sample chamber 12 may be controlled to a lower pressure, as one example, around 0.1 to several tens of Pa, or alternatively may be controlled to be 0.1 Pa or higher, 0.5 Pa or higher, 10 Pa or lower, or 5 Pa or lower. As one example, the inside of the sample chamber 12 may be depressurized to around 1 to 10 mTorr (0.13 to 1.3 Pa). By keeping the sample chamber 12 in the depressurized state indicated above, it is possible to generate the plasma 19 at a low temperature using only the sample gas 9. The sample chamber 12 may be a chamber (miniature chamber) of a sufficient size (several millimeters to around several tens of millimeters) to generate the microplasma 19, as one example, a chamber with a length of 1 to 100 mm and a diameter of 1 to 100 mm. By reducing the volume of the sample chamber 12, it is possible to provide a gas analyzer apparatus 1 that has superior real-time performance. The sample chamber 12 may be cylindrical.

The gas analyzer apparatus 1 includes, as the ionization apparatus 10, an electron ionization apparatus (electron ionizer, filament, or EI ion source) 15 that ionizes, via electron impact (electron ionization) the sample gas 9 to be measured, which is supplied from the process 102 via the gas input device 5 and from the sample input 3b. The EI ion source 15 operates in a high vacuum, and even in cases where the process to be monitored in the process chamber 101 is in high vacuum conditions that make it difficult to generate the microplasma 19, the EI ion source 15 will operate at that pressure in the gas analyzer apparatus 1 and can additionally be used for the purpose of adjusting sensitivity. The gas supplying apparatus 5 includes a connecting pipe 5c connected to the process chamber 101, a valve 5a that controls the flow of the sample gas 9 between the connecting pipe 5c and the sample input 3a used for plasma ionization, and a valve 5b that controls the flow of the sample gas 9 between the connecting pipe 5c and the sample input 3b for EI ionization. By switching the valves 5a and 5b using the process controller 105, the detection mode (measurement mode) of the gas analyzer apparatus 1 can be switched automatically or manually. The EI ion source 15 is provided between the sample input 3b and the filter unit 25 and faces a flow path that is common to the flow path of the ion flow 17 from the plasma (microplasma) 19 in the sample chamber 12. Accordingly, the EI ion source 15 is also capable of electron ionization of the sample gas 9 from the gas input apparatus 5, and can ionize the gas from the sample chamber 12 (that is, the gas used to derive the plasma 19) and supply the ionized gas to the first detector 20.

In the present embodiment, when the process controller 105 executes a highly reactive process 102 in a state where the internal pressure of the process chamber 101 is high, as one example, 1 Pa or higher, the valve 5a is opened and the sample gas 9 is supplied to the gas analyzer apparatus 1. The control apparatus 50 of the gas analyzer apparatus 1 generates plasma (microplasma) 19 of the sample gas 9, which differs from the process 102, from the sample gas 9, extracts the ions 17 from the microplasma 19, and performs mass spectrometry. When doing so, the EI ion source (filament) 15 is not working (activated) and the valve (port) 5b is closed. When the internal pressure of the process chamber 101 is low, as one example, when performing measurement at that pressure, the plasma side port (or “valve”) 5a is closed and the EI side port 5b is opened to supply the sample gas 9, the filament is on (that is, EI is activated) and the internal state of the process chamber 101 is monitored.

The gas analyzer apparatus 1 may include an energy filter 28 disposed between the EI ionization source (Ei ionizer) 15 and the filter 25. The energy filter 28 may be a Bessel Box, a CMA (Cylindrical Mirror Analyzer), or a CHA (Concentric Hemispherical Analyzer). A Bessel box-type energy filter 28 is composed of a cylindrical electrode, a disc-shaped electrode (which is at the same potential as the cylindrical electrode) disposed in the center of the cylindrical electrode, and electrodes placed at both ends of the cylindrical electrode, and operates as a band-pass filter that allows only ions with a specific kinetic energy to pass through in keeping with an electric field, which is produced by the potential difference Vba between the cylindrical electrode and the electrodes at both ends, and the potential Vbe of the cylindrical electrode. In addition, soft X-rays produced during the generation of plasma and light generated during gas ionization can be prevented from becoming directly incident on the ion detector (detector) 26 by the disc-shaped electrode disposed in the center of the cylindrical electrode, which reduces noise. In addition, the energy filter 28 can also eliminate ions and neutral particles that are generated at the ion generating part or outside and enter the filter unit 25 in parallel to the central axis, thereby producing a structure that can suppress the detection of such ions and neutral particles.

Examples of the second detector (analyzer or sensor) 80 is an emission spectrometry-type detector, typically an emission spectrometer (optical emission spectrometry (OES) including atomic emission spectrometry (AES)). One example of an OES 80 includes a light receiving or light collecting element 81, such as an objective lens attached, in parallel with the RF supplying mechanism 13 or coaxially with the coil of the RF supplying mechanism 13, to the translucent dielectric wall structure 12a of the sample chamber 12, an optical fiber 82 that guides light from the light collecting element 81, and a spectroscopic analyzer unit (OES unit or OES detector apparatus) 85 that spectroscopically analyzes the light supplied by the optical fiber 82. The spectroscopic analyzer unit 85 may be any type of detector used in the OES 80, such as a sequential or multi-channel detector.

The gas analyzer apparatus 1 includes a control module 30 that controls each module of the analyzer unit 20 under the PCL 50. The control module 30 includes a control module 35 that performs control the mass spectrometer 20. The control module 35 includes a unit 31 that controls the extraction of the plasma 19, a unit 32 that controls the electron ionization apparatus 15, a filter control function (filter control apparatus) 33 that controls the RF and DC voltages of the mass filter 25 to select a region (region of interest (ROI)) of the measurement target (ions) to be measured by the filter 25, and a function (intensity detection apparatus) 34 that controls the detector 26 to acquire a detection current. The control module 35 may include a function of controlling the potential of the lens group of the mass spectrometer 20, a function of controlling the potential of the energy filter 28, and the like. The control unit 32 of the EI unit 15 may include a filament control function that controls the current and voltage of the filament.

The PLC (control apparatus, controller) 50 that is configured to control the gas analyzer apparatus 1 includes computer resources such as a CPU 56 and a memory 55, and controls the gas analyzer apparatus 1 by loading and executing a program (or program product) 59. The program 59 includes instructions for implementing and operating each function described below of the PLC 50. The PLC 50 includes a function as a generation apparatus (generation device) 57b that is configured to generate synchronized analysis data (data for analysis) 53 by associating and compensating the time lag (delay, time difference, time interval) of the first detection result 51 of the first detector 20 with the second detection result 52 of the second detector 80. The program 59 can be recorded on and provided as a computer-readable medium.

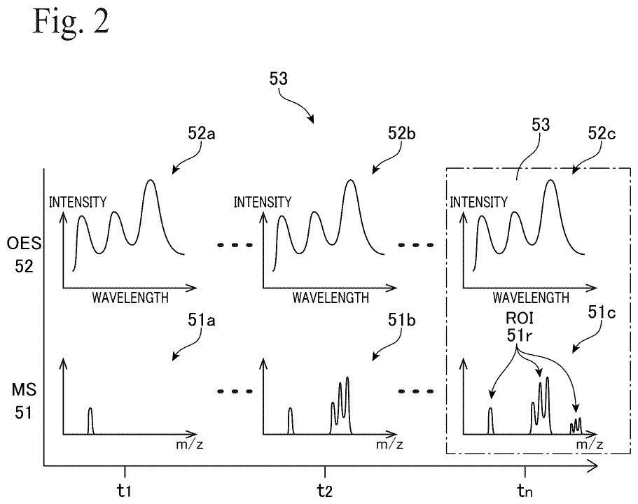

FIG. 2 schematically depicts the first detection results 51 and the second detection results 52. One example of the first detector 20 is a mass spectrometer (MS) that measures the mass and intensity of ionized elements in the plasma. One example of the first detection results 51 is intensity relative to mass-to-charge ratio (m/z). One example of the second detector 80 is an optical detector (OES) that measures the wavelength and intensity of light emitted from elements that have been excited within the plasma. One example of the second detection results 52 is intensity relative to wavelength. Examples of features (advantages) that the first detector (MS) 20 has over the second detector (OES) 80 include high sensitivity, a wide dynamic lens, quantitative measurement of multiple elements, isotope ratio measurement, and simple spectra. Drawbacks include a fall in resolution due to interference between mass spectra.

In other words, the MS 20 is superior in terms of sensitivity, so that while the OES 80 is sensitive to around sub-ppb level, the MS 20 can detect at sub-ppt level. On the other hand, in terms of measurement time, since the output of the OES 80 is an emission spectrum, the second detection result 52 can fundamentally be obtained at the spectrometer sensitivity, and even when the number of elements (components) contained in the sample gas 9 increases, there is no change in measurement time (detection time). The second detection result 52 includes information on every element (component) within the range where a spectrum can be obtained. At the MS 20, measurement is performed while changing the conditions of the filter 25 according to time division, which means that the measurement time depends on the number of elements and mass values to be measured, with the first detection result 51 including only data on measurement targets (that is mass values to be measured). From the viewpoint of spectral interference, the MS 20 cannot separate elements (components) with the same mass-to-charge ratio m/z, and the OES 80 has difficulty separating elements (components) whose spectra are at the same or similar frequencies.

Accordingly, when focusing on measurement time, as depicted in FIG. 2, the first detection results 51 include a mass spectrum acquired by time division (that is, as time passes), which is to say, serially (sequentially) acquired. That is, after acquisition of the spectrum commences at time t1 (51a), as indicated at time t2, mass-to-charge ratios m/z is searched in order (51b), and at time tn, a detection result (the mass spectrum 51c) including a desired mass-to-charge m/z region (or region of interest (ROI)) 51r can be obtained. Even with a relatively high-speed MS, around 1 ms (millimeter second) is required to measure with filter conditioning that is required for setting each m/z, making it possible to measure 1000 points (m/z values) in one second, but this means that the measurement time is greatly increased (required) compared to the OES 80. In addition, when attempts are made to increase the detection sensitivity (that is, the quantitative measurement sensitivity), more time is consumed due to the increase in measurement time per single point. On the other hand, when time is spent on measurement, highly accurate measurement is possible. That is, highly sensitive measurement results (detection results) 51 can be obtained when components are measured by limiting the desired ROI.

On the other hand, the second detection result 52 includes an emission spectrum that can be acquired by spectrometry in parallel with, at least instantaneously (in the order of ms or shorter) to the first detection result 51. Accordingly, the second detection results 52a, 52b and 52c acquired at times t1, t2 and tn will be identical so long as the state of the microplasma 19 does not change. This means that the reliability of a serially acquired first detection result 51 can be ensured by synchronizing (compensating difference of time, taking the time lag into account) and associating the second detection results 52 and the first detection result 51 acquired in parallel. Synchronizing the first detection result 51 and the second detection results 52 mainly involves two latencies that are unique to the gas analyzer apparatus 1.

One factor that causes a time lag (time delay, time interval) is that the first detection results 51 are the results of filtering the ion flow 17 supplied from the microplasma 19 using the filter 25, meaning that time is taken for the ions to physically reach the detector 26. That is, when the microplasma 19 fluctuates, it will take time for the ions to physically reach the detector 26 of the first detector 20 so that such fluctuations can be detected, resulting in a time lag (or latency) relative to the state (instantaneous state, real state) of the plasma 19.

On the other hand, the second detection result 52 is an emission spectrum, and if the state of the microplasma 19 fluctuates, such fluctuations will appear in the detection result with no time lag. However, in the gas analyzer apparatus 1, the subject (object, purpose) of testing by the first detector 20 and the second detector 80 is the microplasma 19 generated in the sample chamber 12 which is fixed to the first detector 20, so that the time lag between the first detection result 51 and the second detection result 52 can be set in advance as a unique value for the gas analyzer apparatus 1. Accordingly, the time difference (time lag) between the first detection result 51 and the second detection result 52 is known by the generation device 57b, and the analysis data 53 in which the first detection result 51 and the second detection result 52 have been synchronized or compensated the time difference (time lag), can be generated. By doing so, detection results for the microplasma 19 produced at the same time by different methods can be obtained with high accuracy.

Another factor is that as described above, at the first detector 20, a predetermined time is required to acquire a first detection result (a scanned first detection result, or mass spectrum) including a desired ROI. As one example, if there is a change in the state of the microplasma 19 while scanning a mass spectrum, the mass spectrum 51c obtained at time tn may not reflect the state of the microplasma 19 at the time tn. On the other hand, if there is no change in the second detection results 52a to 52c while scanning this mass spectrum, it can be guaranteed that the mass spectrum 51c obtained at time tn reflects the state of the microplasma 19 at time tn. To guarantee the reliability of the mass spectrum 51, the generation device (module) 57b may synchronize (compensate the time difference of) the second detection results 52 while the mass spectrum 51 is being acquired to generate the analysis data 53. The generator 57b verifies that all the second detection results 52a to 52c are the same during the acquisition of the mass spectrum 51, may generate the analysis data (data for analysis) 53 by synchronizing (compensating the time difference of, considering the time lag of) the mass spectrum 51c with the second detection result 52c only when all of the second detection results 52a to 52c are the same, and may discard the mass spectrum 51c when this condition is not satisfied. The generation device 57b may store the analysis data 53 generated in this way in the memory 55, or may output the data via the communication apparatus 57d to an external server or the process controller 105.

That is, the gas analyzer apparatus 1 includes the sample chamber 12 that generates the plasma 19, which serves as both the ion source and emission source (light emission source), separately or independently from the process 102, and includes the first detector 20 and the second detector 80 on the fixed routes with respect to the sample chamber 12. Accordingly, the first detection results 51, which are acquired serially, and the second detection results 52, which are acquired in parallel, for the same plasma 19 that is generated inside the sample chamber 12 can be synchronously acquired, and such data can be associated in time by the generation device 57b to generate and output the data 53 for analysis. This means that by checking for fluctuations in the second detection results 52 that are acquired in parallel during the time period in which a first detection result 51 is being acquired serially, it is possible to verify that the first detection result 51 is information from the plasma 19 under the same conditions (as examples, plasma from the identical process under the same conditions or plasma being maintained at the same conditions), which means that even more reliable analysis results can be obtained.

Extremely fine microplasma 19 is generated in the sample chamber 12 of the gas analyzer apparatus 1. This means that the volume of the common ion source and emission source subject to detection by the first detector 20 and the second detector 80 can be reduced, which reduces bias (variety, distribution) and the like in the plasma and makes it possible for the first detection result 51 and the second detection results 52 to be obtained for the same plasma. In addition, it is also possible to limit the mass spectrum 51 that is serially obtained to a region of interest (ROI) 51r, to check information for a wide range using the second detection results 52 that are obtained in parallel, and it makes be possible to acquire information on the ROI using the first detection result 51 produced serially using sufficient time to be required. That is, as depicted in FIG. 2, the first detection results 51 may include a mass spectrum 51c, and in particular, only the mass spectrum 51c limited to the ROI 51r. This means that it is possible, while still confirming information for a wide range, to obtain an even more accurate analysis result for the ROI, even at short time intervals.

The PLC 50 further includes a plasma generation control apparatus (plasma generator controller) 57a that controls the generation state of the microplasma 19 via the plasma controller 16, an ROI control apparatus (ROI controller) 57c for performing control over the filter 25 of the first detector 20 so that a mass spectrum in the desired ROI range can be obtained, and a communication control apparatus (communication controller) 57d for wired or wireless communication with the process controller 105 and/or other external server or the like.

The PCL 50 may additionally include an analyzer (analysis unit, analysis module or analysis function) 70 that analyzes components (elements) contained in the sample gas 9 based on the analysis data 53 including the first detection result 51 and the second detection result 52. The analyzer 70 may include a first analyzer (first analyzer unit, first analysis function, first analysis module) 71 that analyzes the sample gas 9 based on the first detection result 51 and a second detection result 52 that has been synchronized with the first detection result 51 with a time lag defined (fixed) by the gas analyzer apparatus 1.

As described earlier, from the viewpoint of spectral interference, the first detector (MS) 20 cannot separate elements (components) with the same mass-to-charge ratio m/z, and it is difficult for the second detector (OES) 80 to separate elements (components) with spectra having the same or similar frequencies. Conversely, it may be possible to separate components, which cannot be separated in the first detection result 51 of the first detector 20, in the second detection result 52 of the second detector 80, and to separate components, which cannot be separated in the second detection result 52 of the second detector 80, in the first detection result 51 of the first detector 20. In addition, in the analyzer apparatus 1 according to the present embodiment, the analysis data 53 is obtained by combining the first detection result 51, which is highly reliable, and the second detection result 52 which are temporally synchronized. Accordingly, at the first analyzer 71, by cooperatively analyzing such data, it is possible to analyze the components of the sample gas 9 with higher accuracy.

The analyzer (cooperative control module) 70 performs processing that acquires an analysis result produced by processing the detection result 51 of the first detector 20 and the detection results 52 of the second detector 80 in parallel or with a time lag defined (inherent, unique) by the gas analyzer apparatus 1. In this process, since the gas analyzer apparatus 1 includes an electron ionizer 15 in addition to the sample chamber 12, it is possible to select the following processing methods (processing modes), and the analyzer 70 may include a second analyzer (second analysis function, second analysis module) 72 which selects and performs analysis according to one of the following modes M1, M2 and M3.
(1) Detection of ionized components in the plasma 19 by the first detector 20 and emission analysis (optical emission analysis) by the second detector 80 are performed in parallel (first mode, M1).
(2) Detection of components by the first detector 20 by ionizing a gas derived from the plasma 19 using the electron ionizer 15, and emission analysis by the second detector 80 are performed in parallel (second mode, M2).
(3) Detection, by the first detector 20, of components through ionization by the electron ionizer 15 of the sample gas 9 supplied via the sample input 3b and not via the plasma 19, and emission analysis by the second detector 80 of the plasma 19 are performed in parallel (third mode, M3).

By selecting or combining these processes, the components, states, concentrations of each component, changes over time, and the like of the sample gas 9 can be measured accurately.

Note that for processing aside from the third mode, the sample input 3b is closed by the valve 5b positioned upstream. When the inside of the process chamber 101 has a negative pressure (that is, a vacuum) to an extent where it is difficult to generate the plasma 19, the sample input 3a is closed by the upstream valve 5a and sample gas 9 supplied from the sample input 3b may be ionized by the electron ionizer 15. In this case, since no microplasma 19 is formed, a detection result 52 produced by the second detector (OES) 80 is not obtained.

A process monitor (process monitoring apparatus or process monitoring system) 100 includes a process controller (process controller apparatus) 105 that controls the process 102 according to the result of analyzing the sample gas 9, which is supplied from the process chamber 101 where the plasma process 102 is performed, using the gas analyzer apparatus 1. The process controller 105 may include computer resources such as a CPU and memory, and may operate according to a control program (program product) 109. The process controller 105 may include the analyzer 70 whose configuration is the same as that of the PLC 50, and may receive the analysis data 53 from the gas analyzer apparatus 1 to analyze the sample gas 9, and may perform control of one or a plurality of processes 102 performed in the process chamber 101.

The process controller 105 includes an apparatus (endpoint controller) 110 that determines an endpoint of at least one plasma process 102 from the result of the gas analyzer apparatus 1 detecting (that is, measuring) the sample gas 9 that contains by-products of the plasma process. This at least one plasma process 102 may include at least one of etching, film formation, and cleaning. In this process monitor 100, the plasma 19 is generated independently of the process chamber 101 in the sample chamber 12 which is controlled by the gas analyzer apparatus 1, so that the detection of components by the first detector (or mass spectrometer, MS) 20 and the detection of components by the second detector (OES) 80 can be synchronously associated with a high degree of accuracy, and the by-products of the process 102 can be analyzed not only in terms of presence or absence but also in qualitative terms. Accordingly, the process controller 105 can appropriately control the plasma process 102 based on this analysis.

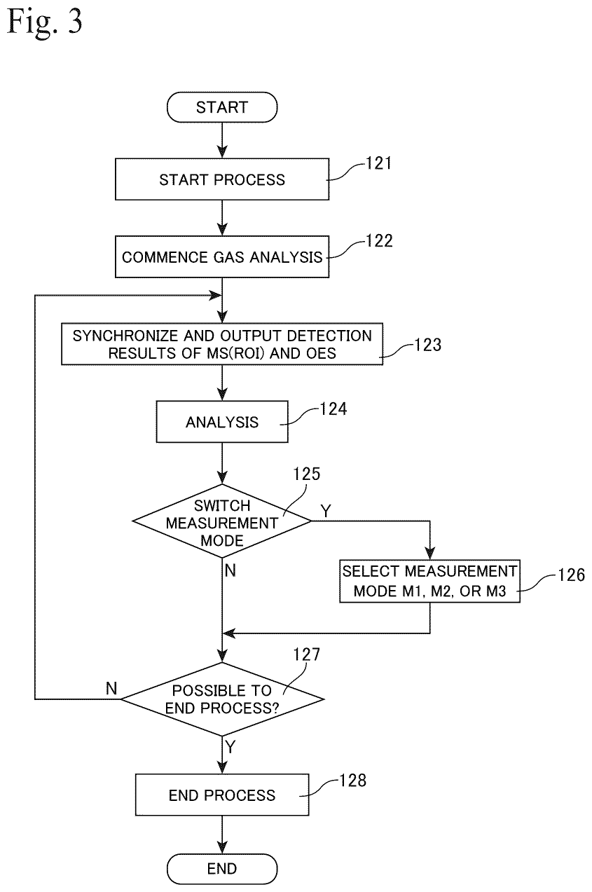

FIG. 3 is a flowchart depicting an overview of how the process controller 105 controls the plasma process 102. In step 121, the process 102 in the process chamber 101 is commenced. At the same time as or before or after this, in step 122, the process controller 105 commences analysis of the sample gas 9 by the gas analyzer apparatus 1. At the gas analyzer apparatus 1, in step 123, the components of the plasma 19 in the sample chamber 12 are detected by the first detector (MS) 20 and the second detector (OES) 80, and the first detection result 51 and the second detection result 52 are synchronized and associated to generate the analysis data 53. In the second detection result 52, information on a wide range of components can be obtained from the emission spectra that are collectively obtained in parallel. In the first detection result 51, it is possible to acquire only a mass spectrum (MS) that is limited to the region of interest (ROI), so that highly accurate and highly sensitive information can be obtained.

In step 124, the first analyzer 71 analyzes the components of the sample gas 9 based on the analysis data 53. In step 125, when the measurement mode needs to be switched, in step 126 one of the first mode (M1), the second mode (M2) and the third mode (M3) may be selected.

In step 127, the endpoint controller 110 of the process controller 105 determines the state and end timing of the process 102 based on the analysis results of the sample gas 9, and when it is determined that the conditions for ending the process 102 have been met, in step 128, the process 102 is terminated. The end of the process 102 may be determined by the endpoint controller 110 based on a detection result for by-products of the plasma process 102 provided by the gas analyzer apparatus 1. After this, it is possible to perform preparations for commencing the next process so that products can be manufactured by repeating sequential processes.

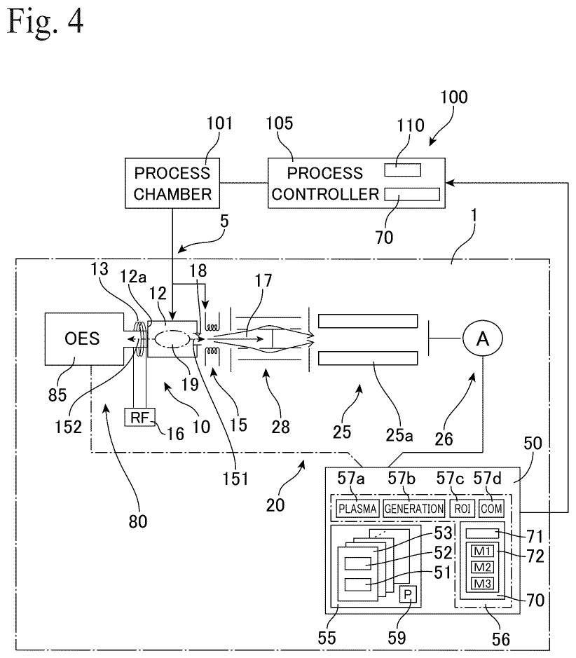

FIG. 4 depicts a different example of the process monitoring apparatus 100. This process monitoring apparatus 100 includes a different example of the gas analyzer apparatus 1. In this gas analyzer apparatus 1, the spectroscopic analyzer unit 85 of the second detector 80 is disposed so as to be directly connected to the translucent dielectric wall structure 12a of the sample chamber 12. Accordingly, it is possible to perform spectroscopic analysis of the light from the plasma 19 in the sample chamber 12 without the light passing through an optical fiber, which means that the results of spectroscopic analysis can be obtained with higher accuracy. Also, by disposing the spectroscopic analyzer unit 85 adjacent to or coaxially with the wall 12a to which the RF for generating plasma is supplied, it is possible to generate the plasma 19 so that the inner surface of the wall 12a becomes treated by the plasma 19. This means that it is possible to completely avoid a situation where the inner surface of the wall 12a is contaminated by derivatives of the plasma 19 and the emitted light becomes difficult to see.

The gas analyzer apparatus 1 includes a first path 151 for supplying an ionized gas flow (ion flow) 17 from an opening 18 provided at one end of the sample chamber 12 to the first detector 20 and a second path 152 for supplying light from the other end of the sample chamber 12 for spectroscopic analysis by the second detector 80. The light to be subjected to spectroscopic analysis can be obtained from the opposite direction from which the ion stream 17 flows, which suppress unexpected variations in the second detection result 52 of the second detector 80.

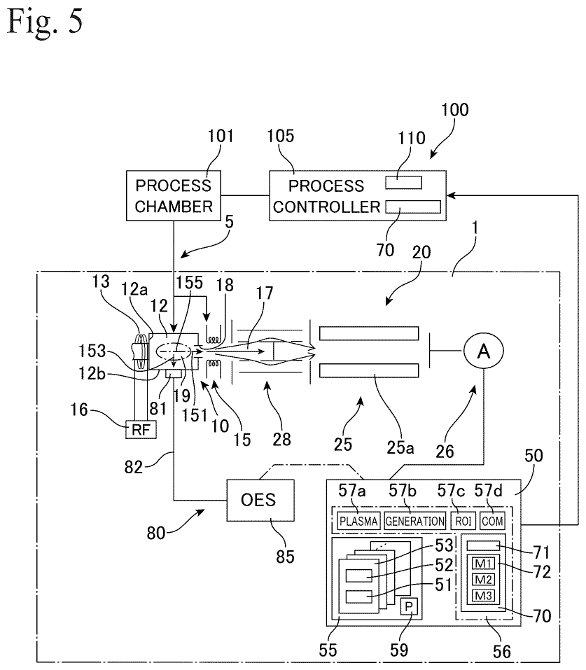

FIG. 5 depicts yet another example of the process monitoring system 100. This process monitoring system 100 includes yet another example of the gas analyzer apparatus 1. The sample chamber 12 of this gas analyzer apparatus 1 is cylindrical with a translucent dielectric side wall 12b and has a light collecting element 81, which is attached to the side wall 12b, for guiding light via an optical fiber 82 to the spectroscopic analyzer unit 85 of the second detector 80. Accordingly, this gas analyzer apparatus 1 includes a first path 151 for supplying an ionized gas flow (ion flow) 17 from an opening 18 provided at one end along a first axis (or center axis) 155 of the sample chamber 12 to the first detector 20 and a third path 153 that supplies light for spectroscopic analysis by the second detector 80 in a direction that is perpendicular to the first axis 155 of the sample chamber 12. The third path 153 allows access from the side to the plasma 19 generated in the cylindrical chamber 12. This means that the second detector 80 can perform optical emission analysis (spectroscopic analysis) using light emitted by an atomized sample in the center of the plasma 19, so that the detection results 52 can be obtained with higher accuracy.

Note that to obtain the light emitted by the plasma 19, the location where the spectroscopic analyzer unit 85 is disposed and the location where the optical fiber 82 is attached are not limited to the above.

The above description discloses a gas analyzer apparatus including: a sample chamber that is provided with a dielectric wall structure and into which a sample gas to be measured flows; a plasma generation mechanism for generating plasma inside the sample chamber, which has been depressurized, using an electric field and/or a magnetic field through the dielectric wall structure; and an analyzer unit (sensor group) that analyzes the sample gas via the generated plasma. The analyzer unit includes a first analyzer (a first detector), for example, a mass spectrometer, that filters ionized gas in the plasma and a second analyzer (a second detector), for example, an optical emission spectrometry analyzer, that performs stereoscopic analysis of ions in the plasma in the sample chamber. This analyzer apparatus is capable of spectroscopically analyzing the ion type and concentration of the plasma, which is the ion source of the first analyzer, using the second analyzer. This makes it possible to analyze a common ionized sample using different methods simultaneously or with a limited time lag (or latency) within the gas analyzer apparatus, and the analysis results from these different methods can be obtained in real time as the analysis results of a single analyzer apparatus. In other words, the analysis unit may include a third analyzer that acquires an analysis result obtained by processing the analysis results of the first analyzer and the analysis results of the second analyzer in parallel or at a time lag defined by the gas analyzer apparatus. In other words, results that capture the ionized gas in the plasma in the sample chamber through different analysis methods without time difference (with time compensation) can be compared in order to analyze the components and concentrations of the sample gas with high precision, including any fluctuations over time.

Since microplasma is formed in the sample chamber, the size of the light source to be subjected to emission spectroscopic analysis can be made sufficiently small, so that stable analysis results can be obtained. The second analyzer may include a unit that receives light from the plasma in the sample chamber through a highly translucent dielectric wall structure, and since the inner surface of the wall structure is constantly refreshed by the plasma, a fall in analysis performance due to dirt or the like is suppressed. In addition, the second analyzer may be a spectroscopic analyzer connected via an optical fiber to the sample chamber, but to eliminate the influence of this optical fiber, the second analyzer may include an optical emission spectrometer that acquires the emission from the sample chamber without passing through the optical fiber. The first analyzer may include an electron ionization unit (electron ionizer) that generates electrons to ionize the sample gas.

A process monitoring system including a gas analyzer apparatus is also disclosed above. This process monitoring system is an example of a system that includes a gas analyzer apparatus and a process chamber in which a plasma process is performed and from which sample gas is supplied to the gas analyzer apparatus.

A method for analyzing components of a sample gas using a gas analyzer apparatus is also disclosed above. This method includes acquiring an analysis result obtained by processing the analysis results of a first analyzer and the analysis results of a second analyzer in parallel or with considering a time lag defined by the gas analyzer apparatus in question. Many benefits are obtained from collaboration between mass spectrometry and optical emission spectrometry. Even if there are components that cannot be separated in mass spectrometry due to them having the same charge ratio, by analyzing the mass spectrometry results while additionally considering ionization types obtained by optical spectroscopic analysis, it is possible to obtain a highly accurate analysis result. When the first analyzer includes an electron ionization unit that generates ions for ionizing the sample gas, the method may include the following measurement methods.
(1) Analysis of ionized gas in plasma by a first analyzer and analysis of gas in the plasma by the second analyzer are performed in parallel.
(2) Analysis, through ionization by an electron ionizer, by the first analyzer of a gas derived from plasma, and analysis of gas in the plasma by the second analyzer are performed in parallel.
(3) Analysis by the first analyzer of gas ionized by the electron ionizer without using plasma, and analysis of gas in the plasma by the second analyzer are performed in parallel.

The above description also discloses a method of controlling a system with a process chamber for performing a plasma process. This system includes the analyzer apparatus described above, causes only sample gas from the process chamber to flow into the sample chamber, and includes controlling the plasma process performed in the process chamber based on the measurement results of the gas analyzer apparatus.

Note that although an example of a mass filter that uses a quadrupole type as the filter 25 of the first detector 20 has been described above, this filter 25 may be a different type, such as an ion trap or a Wien filter.

Although specific embodiments of the present invention have been described above, various other embodiments and modifications will be conceivable to those of skill in the art without departing from the scope and spirit of the invention. Such other embodiments and modifications are addressed by the scope of the patent claims given below, and the present invention is defined by the scope of these patent claims.

1. A gas analyzer apparatus comprising:
a sample chamber that is provided with a dielectric wall structure and into which a sample gas to be measured flows;
a plasma generation mechanism configured to generate a plasma in the sample chamber, which has been depressurized, using an electric field and/or a magnetic field through the dielectric wall structure;
a gas input apparatus configured to cause only the sample gas to flow from a process into the sample chamber;
an electron ionization apparatus configured to ionize a part of the sample flown from the gas input apparatus;
a first detector configured to output a first detection result for analyzing components of the sample gas with filtering ionized gas by the electron ionization apparatus;
a second detector configured to output a second detection result for analyzing components of the sample gas with detecting light emission of ions in the plasma inside the sample chamber; and
an exhaust system configured to keep the sample chamber and a housing, which includes the electron ionization apparatus and the first detector, under negative pressure conditions.

2. The gas analyzer apparatus according to claim 1,
further comprising a generation device configured to output the first detection result and the second detection result synchronously as data for analysis.

3. The gas analyzer apparatus according to claim 2,
wherein the first detection result includes a mass spectrum, and
the second detection result includes an emission spectrum.

4. The gas analyzer apparatus according to claim 3,
wherein the mass spectrum includes a mass spectrum limited to a region of interest.

5. The gas analyzer apparatus according to claim 1,
wherein the sample chamber is integrated with the housing; and
further includes an optical path that supplies light for spectroscopic analysis by the second detector from another end of the sample chamber to an end connecting to the housing.

6. The gas analyzer apparatus according to claim 1,
wherein the dielectric wall structure includes at least one of quartz, aluminum oxide, and silicon nitride, and
the gas analyzer apparatus includes a light guide that directs light from the plasma in the sample chamber through the dielectric wall structure to the second detector.

7. The gas analyzer apparatus according to claim 5,
wherein the plasma generation mechanism includes a coil of an RF supplying mechanism attached to the another end of the sample chamber, and the optical path is attached to the another end of the sample chamber coaxially with the coil.

8. The gas analyzer apparatus according to claim 1,
wherein the second detector includes an optical emission analyzer connected via an optical fiber to the sample chamber.

9. The gas analyzer apparatus according to claim 1,
wherein the sample chamber has a total length of 1 to 100 mm and a diameter of 1 to 100 mm.

10. A process monitoring apparatus comprising the gas analyzer apparatus according to claim 1.

11. A system comprising:
the gas analyzer apparatus according to claim 1; and
a process chamber in which a plasma process is performed and from which the sample gas is supplied to the gas analyzer apparatus.

12. The system according to claim 11,
further comprising a process control apparatus that controls at least one process performed in the process chamber based on a measurement result of the gas analyzer apparatus.

13. The system according to claim 12,
wherein the process control apparatus includes a device that is configured to determine an endpoint of the at least one plasma process according to a measurement result for a by-product of the at least one plasma process produced by the gas analyzer apparatus.

14. A method of controlling a system including a gas analyzer apparatus,
wherein the gas analyzer apparatus includes: a sample chamber that is provided with a dielectric wall structure and into which a sample gas to be measured flows; a plasma generation mechanism for generating plasma inside the sample chamber, which has been depressurized, using an electric field and/or a magnetic field through the dielectric wall structure; a gas input apparatus configured to cause only the sample gas to flow from a process into the sample chamber; an electron ionization apparatus configured to ionize a part of the sample flown from the gas input apparatus; a first detector configured to output a first detection result for analyzing components of the sample gas with filtering ionized gas by the electron ionization apparatus; a second detector configured to output a second detection result for analyzing components of the sample gas with detecting light emission of ions in the plasma in the sample chamber; and an exhaust system configured to keep the sample chamber and a housing, which includes the electron ionization apparatus and the first detector, under negative pressure conditions,
the method comprising outputting in synchronization a first detection result of the first detector and a second detection result of the second detector.

15. The method according to claim 14,
wherein the outputting in synchronization includes outputting the first detection result, which includes a mass spectrum, and outputting the second detection result, which includes an emission spectrum.

16. The method according to claim 15,
wherein the mass spectrum includes a mass spectrum limited to a region of interest.

17. The method according to claim 14,
wherein the system includes a process chamber in which a plasma process is performed and from which the sample gas is supplied via the gas input apparatus into the gas analyzer apparatus, and
the method further comprises controlling a plasma process performed in the process chamber based on a detection result of the plasma generated in the sample chamber of the gas analyzer apparatus independently of the process chamber.

18. The method according to claim 17,
wherein controlling the plasma process includes determining an endpoint of at least one plasma process based on a detection result of the gas analyzer apparatus for a by-product of the at least one plasma process.

19. The method according to claim 18,
wherein the at least one plasma process includes at least one of etching, film formation, and cleaning.

20. A computer readable media that includes a program product that enables a computer to control a system including a gas analyzer apparatus according to the method according to claim 14,
wherein the program product comprises instructions for executing the method according to claim 14.
